(19) United States
(12) Patent Application Publication
(10) Pub. No.: US 2025/0056925 A1
(43) Pub. Date: Feb. 13, 2025

(54) Display Device

(71) Applicant: LG Display Co., Ltd., Seoul (KR)

(72) Inventors: Dojin Kim, Seoul (KR); Eunjeong Shin, Paju-si (KR)

(21) Appl. No.: 18/745,483

(22) Filed: Jun. 17, 2024

(30) Foreign Application Priority Data
Aug. 11, 2023 (KR) 10-2023-0105404

(51) Int. Cl. H01L 33/20; H01L 25/075; H01L 33/62

(52) U.S. Cl. CPC H01L 33/20; H01L 25/0753; H01L 33/62

(57) ABSTRACT

Provided is a display device. The display device comprises a substrate including an active area in which a plurality of sub pixels is disposed and a non-active area. The display device comprises a plurality of transistors disposed in each of the plurality of sub pixels on the substrate. The display device comprises a plurality of light emitting diodes disposed in each of the plurality of sub pixels on the substrate. The display device comprises a plurality of first alignment keys disposed on the substrate. The display device comprises an insulating layer which includes a plurality of inorganic insulating layers and a plurality of organic insulating layers disposed on the substrate. In an area which overlaps the plurality of first alignment keys, the plurality of organic insulating layers is disposed on the plurality of inorganic insulating layers.

### CROSS-REFERENCE TO RELATED APPLICATION

This application claims the priority of Republic of Korea Patent Application No. 10-2023-0105404 filed on Aug. 11, 2023, in the Korean Intellectual Property Office, which is hereby incorporated by reference in its entirety.

### FIELD

The present disclosure relates to a display device, and more particularly, to a display device which is capable of improving a transfer precision of a plurality of light emitting diodes.

### DESCRIPTION OF THE RELATED ART

As display devices which are used for a monitor of a computer, a television, a cellular phone, or the like, there are an organic light emitting display (OLED) device, which is a self-emitting device, a liquid crystal display (LCD) device, which requires a separate light source, and the like.

An applicable range of the display device is diversified to personal digital assistants as well as monitors of computers and televisions and a display device with a large display area and a reduced volume and weight is being studied.

Further, in recent years, a display device including a light emitting diode is attracting attention as a next generation display device. Since the light emitting diode is formed of an inorganic material, rather than an organic material, reliability is excellent so that a lifespan thereof is longer than that of the liquid crystal display device or the organic light emitting display device. Further, the light emitting diode has a fast-lighting speed, excellent luminous efficiency, and a strong impact resistance so that a stability is excellent and an image having a high luminance can be displayed.

### SUMMARY

An object to be achieved by the present disclosure is to provide a display device which improves a transfer precision of a plurality of light emitting diodes by minimizing or at least reducing a medium change in a sensing area of a displacement sensor.

Another object to be achieved by the present disclosure is to provide a display device which minimizes or at least reduces a sensing error by minimizing or reducing a spectral interference in a sensing area of a displacement sensor.

Objects of the present disclosure are not limited to the above-mentioned objects, and other objects, which are not mentioned above, can be clearly understood by those skilled in the art from the following descriptions.

According to an aspect of the present disclosure, there is provided a display device. The display device comprises a substrate including an active area in which a plurality of sub pixels is disposed and a non-active area. The display device comprises a plurality of transistors disposed in each of the plurality of sub pixels on the substrate. The display device comprises a plurality of light emitting diodes disposed in each of the plurality of sub pixels on the substrate. The display device comprises a plurality of first alignment keys disposed on the substrate. The display device comprises an insulating layer which includes a plurality of inorganic insulating layers and a plurality of organic insulating layers disposed on the substrate. In an area which overlaps the plurality of first alignment keys, the plurality of organic insulating layers is disposed on the plurality of inorganic insulating layers.

According to another aspect of the present disclosure, there is provided a display device. The display device comprises a substrate which includes a first area and a second area. The display device comprises a plurality of transistors and a plurality of light emitting diodes disposed in the first area. The display device comprises a plurality of alignment keys disposed in the second area. The display device comprises a plurality of insulating layers disposed on the substrate in the first area and the second area. The plurality of insulating layers includes a plurality of inorganic insulating layers and a plurality of organic insulating layers disposed in the first area and the second area, at least one of the plurality of organic insulating layers is disposed between the plurality of inorganic insulating layers in the first area, and in the second area, the plurality of organic insulating layers is disposed on the plurality of inorganic insulating layers.

Other detailed matters of the exemplary embodiments are included in the detailed description and the drawings.

According to the present disclosure, a plurality of light emitting diodes with an ultra-fine size may be easily aligned.

According to the present disclosure, the lowering of the yield according to an alignment error in the process during the transferring of the plurality of light emitting diodes may be minimized or at least reduced.

According to the present disclosure, a transfer error during the transferring of the plurality of light emitting diodes is reduced to optimize the manufacturing process of the display device and improve a productivity.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic diagram of a display device according to an exemplary embodiment of the present disclosure;

FIG. 2A is a partial cross-sectional view of a display device according to an exemplary embodiment of the present disclosure;

FIG. 2B is a perspective view of a tiling display device according to an exemplary embodiment of the present disclosure.

FIG. 3 is a plan view of a display panel of a display device according to an exemplary embodiment of the present disclosure;

FIGS. 4A and 4B are plan views illustrating a pixel area of a display device according to an exemplary embodiment of the present disclosure;

FIG. 5 is a cross-sectional view of a pixel area of a display device according to an exemplary embodiment of the present disclosure;

FIG. 6 is a cross-sectional view taken along the line VI-VI′ of FIG. 3 according to an exemplary embodiment of the present disclosure;

FIG. 7 is a schematic process diagram for explaining a manufacturing method of a display device according to an exemplary embodiment of the present disclosure; and

FIG. 8 is a cross-sectional view of a display device according to another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

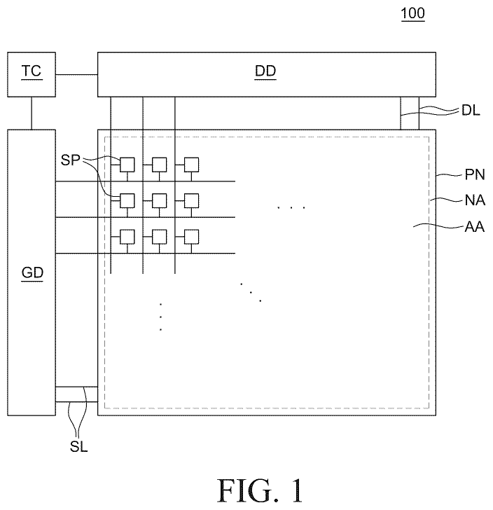

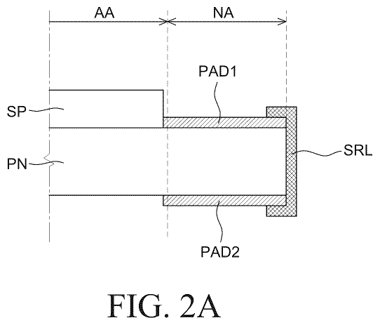

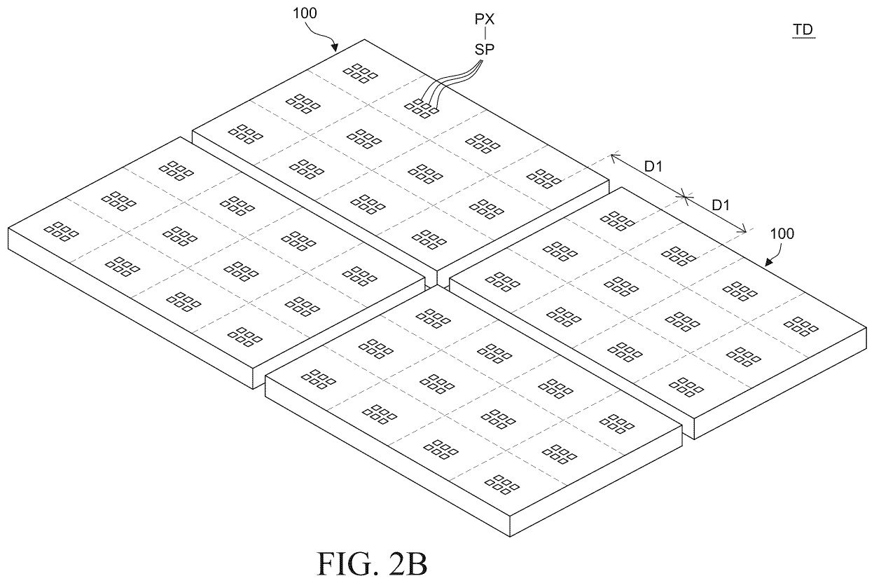

FIG. 1 is a schematic diagram of a display device according to an exemplary embodiment of the present disclosure. FIG. 2A is a partial cross-sectional view of a display device according to an exemplary embodiment of the present disclosure. FIG. 2B is a perspective view of a tiling display device according to an exemplary embodiment of the present disclosure. In FIG. 1, for the convenience of description, among various components of the display device 100, only a display panel PN, a gate driver GD, a data driver DD, and a timing controller TC are illustrated.

Referring to FIG. 1, the display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD converts image data input from the timing controller TC into a data voltage using a reference gamma voltage in accordance with a plurality of data control signals supplied from the timing controller TC. The data driver DD may supply the converted data voltage to the plurality of data lines DL.

The timing controller TC aligns image data input from the outside to supply the image data to the data driver DD. The timing controller TC may generate a gate control signal and a data control signal using synchronization signals input from the outside, such as a dot clock signal, a data enable signal, and horizontal/vertical synchronization signals. The timing controller TC supplies the generated gate control signal and data control signal to the gate driver GD and the data driver DD, respectively, to control the gate driver GD and the data driver DD.

The display panel PN is a configuration which displays images to the user and includes the plurality of sub pixels SP. In the display panel PN, the plurality of scan lines SL and the plurality of data lines DL intersect each other and the plurality of sub pixels SP are connected to the scan lines SL and the data lines DL, respectively. In addition, even though it is not illustrated in the drawing, each of the plurality of sub pixels SP may be connected to a high potential power line, a low potential power line, a reference line, and the like.

In the display panel PN, an active area AA and a non-active area NA enclosing the active area AA may be defined.

The active area AA is an area in which images are displayed in the display device 100. In the active area AA, a plurality of sub pixels SP which configures a plurality of pixels PX and a circuit for driving the plurality of sub pixels SP may be disposed. The plurality of sub pixels SP is a minimum unit which configures the active area AA and n sub pixels SP may form one pixel. In each of the plurality of sub pixels SP, a light emitting diode, a thin film transistor for driving the light emitting diode, and the like may be disposed. The plurality of light emitting diodes may be defined in different manners depending on the type of the display panel PN. For example, when the display panel PN is an inorganic light emitting display panel, the light emitting diode may be a light emitting diode (LED) or a micro light emitting diode (LED).

In the active area AA, a plurality of wiring lines which transmit various signals to the plurality of sub pixels SP are disposed. For example, the plurality of wiring lines may include a plurality of data lines DL which supply a data voltage to each of the plurality of sub pixels SP, a plurality of scan lines SL which supply a scan signal to each of the plurality of sub pixels SP, and the like. The plurality of scan lines SL extend to one direction in the active area AA to be connected to the plurality of sub pixels SP and the plurality of data lines DL extend to a direction different from the one direction in the active area AA to be connected to the plurality of sub pixels SP. In addition, in the active area AA, a low potential power line, a high potential power line, and the like may be further disposed, but are not limited thereto.

The non-active area NA is an area where images are not displayed so that the non-active area NA may be defined as an area extending from the active area AA. In the non-active area NA, a link line which transmits a signal to the sub pixel SP of the active area AA, a pad electrode, or a driving IC, such as a gate driver IC or a data driver IC, may be disposed.

In the meantime, the non-active area NA may be located on a rear surface of the display panel PN, that is, a surface on which the sub pixels SP are not disposed, or may be omitted, and is not limited as illustrated in the drawing.

In the meantime, a driver, such as a gate driver GD, a data driver DD, and a timing controller TC, may be connected to the display panel PN in various ways. For example, the gate driver GD may be mounted in the non-active area NA in a gate in panel (GIP) manner or mounted between the plurality of sub pixels SP in the active area AA in a gate in active area (GIA) manner. For example, the data driver DD and the timing controller TC are formed in separate flexible film and printed circuit board PCB. The data driver DD and the timing controller TC may be electrically connected to the display panel PN by bonding the flexible film and the printed circuit board PCB to the pad electrode formed in the non-active area NA of the display panel PN.

If the gate driver GD is mounted in the GIP manner and the data driver DD and the timing controller TC transmit a signal to the display panel PN through a pad electrode of the non-active area NA, an area of the non-active area NA for disposing the gate driver GD and the pad electrode is necessary more than a predetermined level. Accordingly, a bezel may be increased.

In contrast, when the gate driver GD is mounted in the active area AA in the GIA manner and a side line SRL which connects the signal line on the front surface of the display panel PN to the pad electrode on a rear surface of the display panel PN is formed to bond the flexible film and the printed circuit board onto a rear surface of the display panel PN, the non-active area NA may be minimized on the front surface of the display panel PN. That is, when the gate driver GD, the data driver DD, and the timing controller TC are connected to the display panel PN as described above, a zero bezel with substantially no bezel may be implemented.

Specifically, referring to FIGS. 2A and 2B, in the non-active area NA of the display panel PN, a plurality of pad electrodes PAD1 and PAD2 for transmitting various signals to the plurality of sub pixels SP are disposed. For example, in the non-active area NA on the front surface of the display panel PN, a plurality of first pad electrodes PAD1 which transmit a signal to the plurality of sub pixels SP are disposed. In the non-active area NA on the rear surface of the display panel PN, a plurality of second pad electrodes PAD2 which are electrically connected to a driving component, such as a flexible film and the printed circuit board, are disposed. That is, on the front surface of the display panel PN on which images are displayed, only a pad area of the non-active area NA in which the first pad electrode PAD1 is disposed may be formed at minimum.

In this case, even though it is not illustrated in the drawing, various signal lines connected to the plurality of sub pixels SP, for example, a scan line SL, a data line DL, or the like extends from the active area AA to the non-active area NA to be electrically connected to the first pad electrode PAD1.

The side line SRL is disposed along a side surface of the display panel PN. The side line SRL may electrically connect the first pad electrode PAD1 on the front surface of the display panel PN and the second pad electrode PAD2 on the rear surface of the display panel PN. Therefore, a signal from a driving component on the rear surface of the display panel PN may be transmitted to the plurality of sub pixels SP through the second pad electrode PAD2, the side line SRL, and the first pad electrode PAD1. Accordingly, a signal transmitting path from the front surface of the display panel PN to the side surface and the rear surface is formed to minimize an area of the non-active area NA on the front surface of the display panel PN.

Referring to FIG. 2B, a tiling display device TD having a large screen size may be implemented by connecting a plurality of display devices 100. At this time, as illustrated in FIG. 2A, when the tiling display device TD is implemented using a display device 100 with a minimized bezel, a seam area in which an image between the display devices TD is not displayed is minimized so that a display quality may be improved.

For example, the plurality of sub pixels SP may form one pixel PX and a distance D1 between an outermost pixel PX of one display device 100 and an outermost pixel PX of another display device 100 adjacent to one display device may be implemented to be equal to a distance D1 between pixels PX in one display device 100. Accordingly, a distance D1 of pixels PX between the display devices 100 is constantly configured to minimize the seam area.

However, FIGS. 2A and 2B are illustrative so that the display device according to the exemplary embodiment of the present disclosure may be a general display device with a bezel, but is not limited thereto.

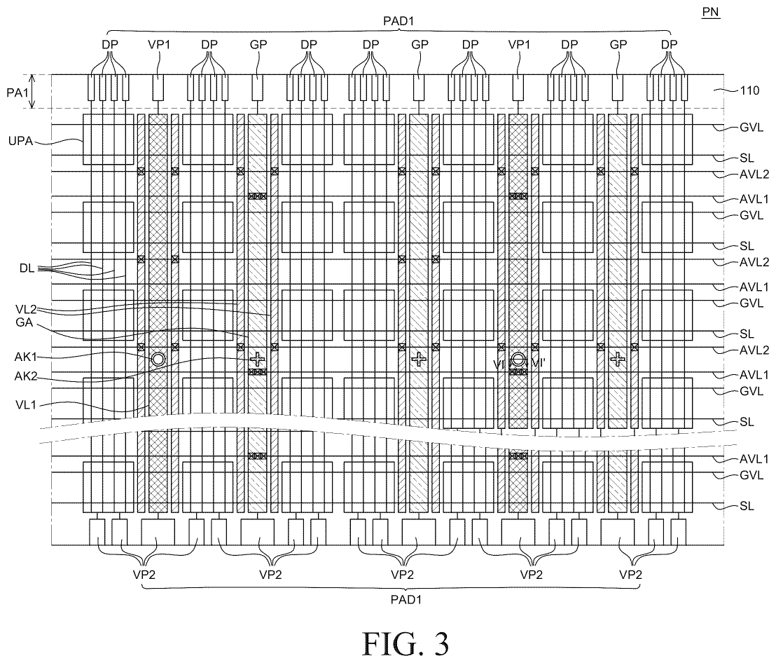

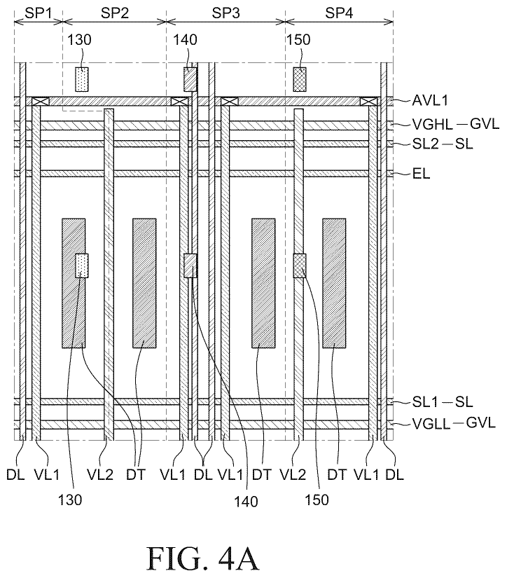

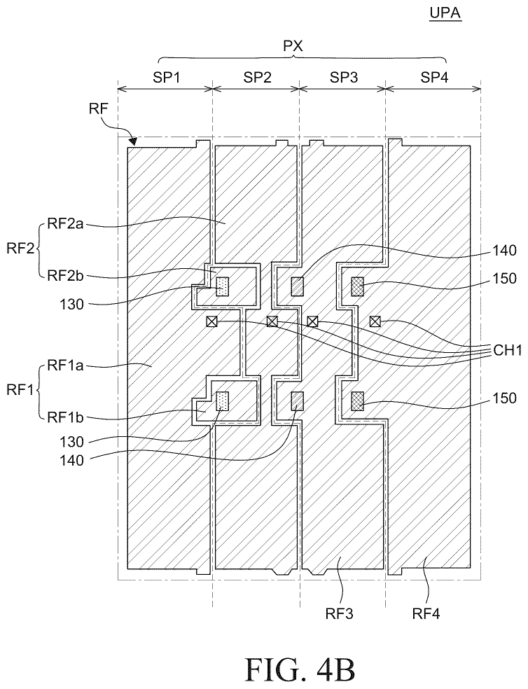

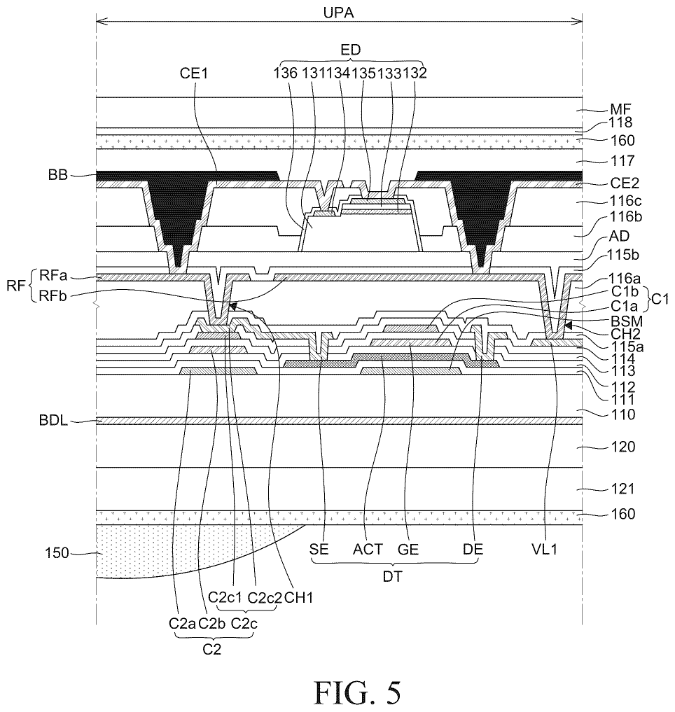

FIG. 3 is a plan view of a display panel of a display device according to an exemplary embodiment of the present disclosure. FIGS. 4A and 4B are plan views illustrating a pixel area of a display device according to an exemplary embodiment of the present disclosure. FIG. 5 is a cross-sectional view of a pixel area of a display device according to an exemplary embodiment of the present disclosure. In FIG. 3, for the convenience of illustration, a center area of the display panel PN is not illustrated. In FIG. 4A, the plurality of light emitting diodes ED, a driving transistor DT of the pixel circuit, and a plurality of wiring lines are illustrated and in FIG. 4B, a plurality of reflection plates RF and a plurality of light emitting diodes ED are illustrated.

First, referring to FIGS. 3 to 5, the display panel PN includes a first substrate 110. The first substrate 110 is a substrate which supports components disposed above the display device 100 and may be an insulating substrate. A plurality of pixels PX is formed on the first substrate 110 to display images. For example, the first substrate 110 may be formed of glass or resin. Further, the first substrate 110 may include polymer or plastic. In some exemplary embodiments, the first substrate 110 may be formed of a plastic material having flexibility.

Referring to FIG. 3, in the first substrate 110, a plurality of pixel areas UPA, a plurality of gate driving areas GA, and a plurality of pad areas are disposed. Among them, the plurality of pixel areas UPA and the plurality of gate driving areas GA may be included in the active area AA of the display panel PN.

First, the plurality of pixel areas UPA are areas in which the plurality of pixels PX are disposed. The plurality of pixel areas UPA may be disposed while forming a plurality of rows and a plurality of columns. Each of the plurality of pixels PX disposed in the plurality of pixel areas UPA includes a plurality of sub pixels SP. Each of the plurality of sub pixels SP includes a light emitting diode ED and a pixel circuit to independently emit light.

The plurality of gate driving areas GA is areas where gate drivers GD are disposed. The gate driver GD may be mounted in the active area AA in a gate in active area (GIA) manner. For example, the gate driving area GA may be formed along a row direction and/or column direction between the plurality of pixel areas UPA. The gate driver GD formed in the gate driving area GA may supply the scan signal to the plurality of scan lines SL.

The gate driver GD disposed in the gate driving area GA may include a circuit for outputting a scan signal. At this time, the gate driver GD may include, for example, a plurality of transistors and/or capacitors. Here, active layers of the plurality of transistors may be formed of a semiconductor material, such as an oxide semiconductor, amorphous silicon, or polysilicon, but are not limited thereto. The active layers of the plurality of transistors may be formed of the same material or different materials from each other. Further, the active layers of the transistors of the gate driver may be formed of the same material as active layers of various transistors of the pixel circuit or formed of different materials from each other.

The plurality of pad areas are areas in which a plurality of first pad electrodes PAD1 are disposed. The plurality of first pad electrodes PAD1 may transmit various signals to various wiring lines extending in a column direction in the active area AA. For example, the plurality of first pad electrodes PAD1 include a data pad DP, a gate pad GP, a high potential power pad VP1, and a low potential power pad VP2. The data pad DP transmits a data voltage to the data line DL and the gate pad GP transmits a clock signal, a start signal, a gate low voltage, and a gate high voltage for driving the gate driver GD to the gate driver GD. The high potential power pad VP1 transmits a high potential power voltage to the high potential power line VL1 and the low potential power pad VP2 transmits a low potential power voltage to the low potential power line VL2.

The plurality of pad areas include a first pad area PA1 located at an upper edge of the display panel PN and a second pad area PA2 of the display panel PN. At this time, in the first pad area PA1 and the second pad area PA2, different types of first pad electrodes PAD1 may be disposed. For example, in the first pad area PA1, among the plurality of first pad electrodes PAD1, the plurality of data pads DP, the plurality of gate pads GP, and the plurality of high potential power pads VP1 may be disposed and in the second pad area PA2, the plurality of low potential power pads VP2 may be disposed.

At this time, the plurality of first pad electrodes PAD1 may be formed to have different sizes, respectively. For example, the plurality of data pads DP which is connected to the plurality of data lines DL one to one may have a smaller width and the plurality of high potential power pads VP1, the plurality of low potential power pads VP2, and the plurality of the gate pads GP may have a larger width. However, widths of the plurality of data pads DP, the plurality of gate pads GP, the plurality of high potential power pads VP1, and the plurality of low potential power pads VP2 illustrated in FIG. 3 are illustrative so that the first pad electrode PAD1 may be configured in various sizes, but is not limited thereto.

Next, the plurality of data lines DL which extend in a column direction from the plurality of first pad electrodes PAD1 are disposed on the first substrate 110 of the display panel PN. The plurality of data lines DL may extend from the plurality of data pads DP of the first pad area PA1 toward the plurality of pixel areas UPA. The plurality of data lines DL extend in a column direction and may be disposed to overlap the plurality of pixel areas UPA. Therefore, the plurality of data lines DL may transmit the data voltage to the pixel circuit of each of the plurality of sub pixels SP.

The plurality of high potential power lines VL1 extending in the column direction are disposed on the first substrate 110 of the display panel PN. Some of the plurality of high potential power lines VL1 extend from the high potential power pad VP1 of the first pad area PA1 to the plurality of pixel areas UPA to transmit the high potential power voltage to the light emitting diodes ED of each of the plurality of sub pixels SP. The others of the plurality of high potential power lines VL1 may be electrically connected to the other high potential power line VL1 by means of an auxiliary high potential power line AVL1 to be described below.

The plurality of low potential power lines VL2 extending in the column direction are disposed on the first substrate 110 of the display panel PN. At least some of the plurality of low potential power lines VL2 extend from the low potential power pad VP2 of the second pad area PA2 to the plurality of pixel areas UPA to transmit the low potential power voltage to the pixel circuit of each of the plurality of sub pixels SP. The others of the plurality of low potential power lines VL2 may be electrically connected to the other low potential power line VL2 by means of an auxiliary low potential power line AVL2 to be described below.

The plurality of scan lines SL extending in the row direction are disposed on the first substrate 110 of the display panel PN. The plurality of scan lines SL extend in the row direction and may be disposed across the plurality of pixel areas UPA and the plurality of gate driving areas GA. The plurality of scan lines SL may transmit the scan signal from the gate driver GD to the pixel circuits of the plurality of sub pixels SP.

A plurality of auxiliary high potential power lines AVL1 extending in the row direction are disposed on the first substrate 110 of the display panel PN. The plurality of auxiliary high potential power lines AVL1 may be disposed in an area between the plurality of pixel areas UPA. The plurality of auxiliary high potential power lines AVL1 extending in the row direction are electrically connected to the plurality of high potential power lines VL1 extending in the column direction through a contact hole and may form a mesh structure. Therefore, the plurality of auxiliary high potential power lines AVL1 and the plurality of high potential power lines VL1 are configured to form a mesh structure to minimize or at least reduce voltage drop and voltage deviation. In the meantime, in the plurality of high potential power lines VL1, a hole which overlaps a plurality of first alignment keys AK1 may be formed.

A plurality of auxiliary low potential power lines AVL2 extending in the row direction are disposed on the first substrate 110 of the display panel PN. The plurality of auxiliary low potential power lines AVL2 may be disposed in an area between the plurality of pixel areas UPA. The plurality of auxiliary low potential power lines AVL2 extending in the row direction are electrically connected to the plurality of low potential power lines VL2 extending in the column direction through a contact hole to form a mesh structure. Therefore, the plurality of auxiliary low potential power lines AVL2 and the plurality of low potential power lines VL2 are configured to form a mesh structure to reduce a resistance of the wiring line and minimize voltage deviation.

Referring to FIGS. 3 and 4A, the plurality of gate driving lines GVL extending in the row direction and the column direction are disposed on the first substrate 110 of the display panel PN. Some of the plurality of gate driving lines GVL extends from the gate pad GP of the first pad area PA1 to the gate driving area GA to transmit a signal to the gate driver GD. The others of the plurality of gate driving lines GVL extend in the row direction and may transmit the signal to the gate drivers GD of the plurality of gate driving areas GA. Therefore, various signals are transmitted from the gate driving line GVL to the gate driver GD to drive the gate driver GD.

The plurality of gate driving lines GVL may include wiring lines which transmit a clock signal, a start signal, a gate high voltage, a gate low voltage, and the like to the gate driver GD. Therefore, various signals are transmitted from the gate driving line GVL to the gate driver GD to drive the gate driver GD.

For example, referring to FIG. 4A, the plurality of gate driving lines GVL may include a gate power line which transmits a power voltage to the gate driver GD of the gate driving area GA. The plurality of gate power lines includes a first gate power line VGHL which transmits a gate high voltage to the gate driver GD and a second gate power line VGLL which transmits a gate low voltage to the gate driver GD.

The plurality of first alignment keys AK1 may be disposed to overlap the plurality of high potential power lines VL1 between the plurality of pixel areas UPA. The plurality of first alignment keys AK1 are components used to align the donor substrate and the display panel PN. Each of the plurality of first alignment keys AK1 is a mark for adjusting a degree of parallelism with the donor substrate when the plurality of light emitting diodes ED of the donor substrate is transferred to the display panel PN. The plurality of first alignment keys AK1 may have a circular ring shape, but is not limited thereto.

The plurality of second alignment keys AK2 may be disposed on a different column from a column in which the plurality of first alignment keys AK1 is disposed. The second alignment key may be disposed in the gate driving area GA between the plurality of pixel areas UPA. The plurality of second alignment keys AK2 may be used to inspect an alignment position of the plurality of light emitting diodes ED. For example, the plurality of second alignment keys AK2 are components used to align the donor substrate and the display panel PN on an X-Y plane. In order to identify the plurality of first alignment keys AK1 and the plurality of second alignment keys AK2, the plurality of second alignment keys AK2 may have a different shape from that of the plurality of first alignment keys AK1. For example, the plurality of second alignment keys AK2 may have a cross shape, but is not limited thereto.

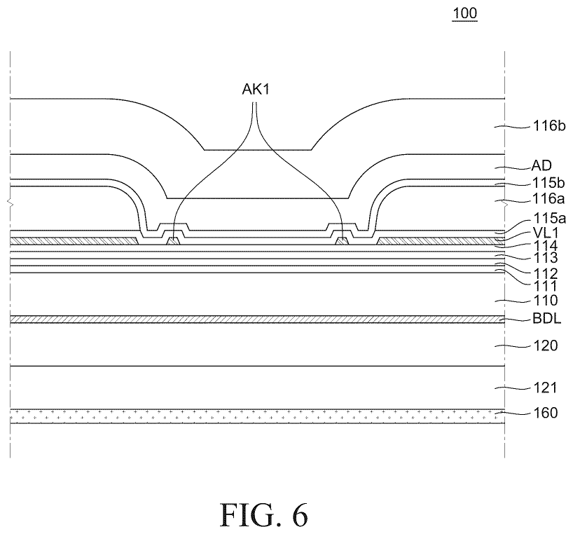

However, the material and the forming process of the plurality of first alignment keys AK1 and the plurality of second alignment keys AK2 may be configured in various forms depending on the design, but are not limited thereto. The plurality of first alignment keys AK1 will be described in more detail below with reference to FIG. 6.

Hereinafter, the plurality of sub pixels SP of the pixel area UPA will be described in more detail with reference to FIGS. 4A to 5.

Referring to FIGS. 4A and 4B, in one pixel area UPA, a plurality of sub pixels SP which forms one pixel PX is disposed. For example, the plurality of sub pixels SP may include a first sub pixel SP1, a second sub pixel SP2, a third sub pixel SP3, and a fourth sub pixel SP4 which emit different color light. For example, the first sub pixel SP1 and the second sub pixel SP2 may be red sub pixels SP, the third sub pixel SP3 may be a green sub pixel SP, and the fourth sub pixel SP4 may be a blue sub pixel SP, but they are not limited thereto.

Referring to FIG. 4A, as described above, a plurality of wiring lines which supplies various signals to the plurality of sub pixels SP is disposed in the plurality of pixel areas UPA of the first substrate 110. For example, the plurality of data lines DL, the plurality of high potential power lines VL1, and the plurality of low potential power lines VL2 extending in the column direction may be disposed on the first substrate 110. For example, the plurality of emission control signal lines EL, the plurality of auxiliary high potential power lines AVL1, the plurality of auxiliary low potential power lines AVL2, the plurality of first scan lines SL1, and the plurality of second scan lines SL2 extending in the row direction may be disposed on the first substrate 110. The high potential power line VL1 extending in the column direction may be electrically connected to the auxiliary high potential power line AVL1 extending in the row direction through a contact hole. At this time, the emission control signal line EL transmits an emission control signal to the pixel circuits of the plurality of sub pixels SP to control emission timings of each of the plurality of sub pixels SP.

Some gate driving lines GVL which transmit signals to each of the plurality of gate drivers GD disposed to be spaced apart from each other with the pixel area UPA therebetween may be disposed across the pixel area UPA while extending to the row direction. For example, a first gate power line VGHL which supplies a gate high voltage to the gate driver GD and a second gate power line VGLL which supplies a gate low voltage may be disposed across the pixel area UPA.

In the meantime, even though it is illustrated that the plurality of scan lines SL includes a first scan line SL1 and a second scan line SL2, the configuration of the plurality of scan lines SL may vary depending on the pixel circuit configuration of the sub pixel SP, but is not limited thereto.

The pixel circuit for driving the light emitting diode ED is disposed in each of the plurality of sub pixels SP on the first substrate 110. The pixel circuit may include a plurality of thin film transistors and a plurality of capacitors. In FIGS. 4A and 5, for the convenience of description, a driving transistor DT, a first capacitor C1, and a second capacitor C2, among configurations of the pixel circuit are illustrated. However, the pixel circuit may further include a switching transistor, a sensing transistor, an emission control transistor, and the like, but is not limited thereto.

Referring to FIG. 5, a bonding layer BDL is disposed between the first substrate 110 and the second substrate 120.

On the first substrate 110, a light shielding layer BSM, a driving transistor DT, a first capacitor C1, a second capacitor C2, a reflection plate RF, a plurality of light emitting diodes ED, a first connection electrode CE1, a second connection electrode CE2, a bank BB, a protection layer 117, an encapsulation layer 160, an adhering unit 118, an optical film MF, and an insulating layer may be disposed. The insulating layer includes a plurality of inorganic insulating layers and a plurality of organic insulating layers.

A second protection layer 121, an encapsulation layer 160, and a seal member 150 are disposed below the second substrate 120.

Among the insulating layers disposed on the first substrate 110, the plurality of inorganic insulating layers includes a buffer layer 111, a gate insulating layer 112, a first interlayer insulating layer 113, a second interlayer insulating layer 114, a first passivation layer 115a, and a second passivation layer 115b.

Further, among the insulating layers disposed on the first substrate 110, the plurality of organic insulating layers may include a first planarization layer 116a, an adhesive layer AD, and a second planarization layer 116b.

Referring to FIG. 5, a light shielding layer BSM is disposed on the first substrate 110. The light shielding layer BSM blocks light which is incident to active layers ACT of the plurality of transistors to minimize or at least reduce a leakage current. For example, the light shielding layer BSM is disposed below the active layer ACT of the driving transistor DT to block light incident onto the active layer ACT. If light is irradiated onto the active layer ACT, a leakage current is generated, which deteriorates the reliability of the transistor. Accordingly, the light shielding layer BSM which blocks the light is disposed on the first substrate 110 to improve the reliability of the driving transistor DT. The light shielding layer BSM may be configured by an opaque conductive material such as copper (Cu), aluminum (Al), molybdenum (Mo), nickel (Ni), titanium (Ti), chrome (Cr), or an alloy thereof, but is not limited thereto.

The buffer layer 111 is disposed on the light shielding layer BSM. The buffer layer 111 is an inorganic insulating layer which reduces permeation of moisture or impurities through the first substrate 110. The buffer layer 111 may be configured by a single layer or a double layer of silicon oxide (SiOx) or silicon nitride (SiNx), but is not limited thereto. However, the buffer layer 111 may be omitted depending on a type of the first substrate 110 or a type of the thin film transistor, but is not limited thereto.

A driving transistor DT including an active layer ACT, a gate electrode GE, a source electrode SE, and a drain electrode DE is disposed on the buffer layer 111.

Even though it is not illustrated in FIG. 5, an additional buffer layer may be disposed between the first substrate 110 and the light shielding layer BSM. The additional buffer layer is an inorganic insulating layer which reduces permeation of moisture or impurities through the first substrate 110, like the buffer layer 111 described above, and may be configured by a single layer or a double layer of silicon oxide (SiOx) or silicon nitride (SiNx), but is not limited thereto.

First, the active layer ACT of the driving transistor DT is disposed on the buffer layer 111. The active layer ACT may be formed of a semiconductor material, such as an oxide semiconductor, amorphous silicon, or polysilicon, but is not limited thereto. Further, even though it is not illustrated in the drawings, other transistors, such as a switching transistor, a sensing transistor, and an emission control transistor, other than the driving transistor DT, may be further disposed. The active layers of the transistors may also be formed of a semiconductor material, such as an oxide semiconductor, amorphous silicon, or polysilicon, but are not limited thereto. The active layer of the transistor included in the pixel circuit, such as the driving transistor DT, the switching transistor, the sensing transistor, and the emission control signal, may be formed of the same material, or formed of different materials.

The gate insulating layer 112 is disposed on the active layer ACT. The gate insulating layer 112 is an inorganic insulating layer which electrically insulates the active layer ACT from the gate electrode GE and may be configured by a single layer or a double layer of silicon oxide (SiOx) or silicon nitride (SiNx), but is not limited thereto.

The gate electrode GE is disposed on the gate insulating layer 112. The gate electrode GE may be configured by a conductive material, such as copper (Cu), aluminum (Al), molybdenum (Mo), nickel (Ni), titanium (Ti), chrome (Cr), or an alloy thereof, but is not limited thereto.

The first interlayer insulating layer 113 and the second interlayer insulating layer 114 are disposed on the gate electrode GE. In the first interlayer insulating layer 113 and the second interlayer insulating layer 114, contact holes through which the source electrode SE and the drain electrode DE are connected to the active layer ACT, respectively, are formed. The first interlayer insulating layer 113 and the second interlayer insulating layer 114 are inorganic insulating layers which protect components there below and may be configured by single layers or double layers of silicon oxide (SiOx) or silicon nitride (SiNx), but are not limited thereto.

The source electrode SE and the drain electrode DE which are electrically connected to the active layer ACT are disposed on the second interlayer insulating layer 114. The source electrode SE is connected to the second capacitor C2 and the first electrode 134 of the light emitting diode ED and the drain electrode DE is connected to the other configuration of the pixel circuit. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto.

The plurality of high potential power lines VL1 are disposed on the second interlayer insulating layer 114. The plurality of high potential power lines VL1 may transmit the high potential power voltage to the light emitting diode ED of each of the plurality of sub pixels SP. The plurality of high potential power lines VL1 may be configured by a conductive material, such as copper (Cu), aluminum (Al), molybdenum (Mo), nickel (Ni), titanium (Ti), chrome (Cr), or an alloy thereof, but is not limited thereto.

Next, the first capacitor C1 is disposed on the gate insulating layer 112. The first capacitor C1 includes a 1-1-th capacitor electrode C1a and a 1-2-th capacitor electrode C1b.

First, the 1-1-th capacitor electrode C1a is disposed on the gate insulating layer 112. The 1-1-th capacitor electrode C1a may be integrally formed with the gate electrode GE of the driving transistor DT.

The 1-2-th capacitor electrode C1b is disposed on the first interlayer insulating layer 113. The 1-2-th capacitor electrode C1b is disposed to overlap the 1-1-th capacitor electrode C1a with the first interlayer insulating layer 113 therebetween.

Therefore, the first capacitor C1 is connected to the gate electrode GE of the driving transistor DT to maintain a voltage of the gate electrode GE of the driving transistor DT for a predetermined period.

Next, the second capacitor C2 is disposed on the first substrate 110. The second capacitor C2 includes a 2-1-th capacitor electrode C2a, a 2-2-th capacitor electrode C2b, and a 2-3-th capacitor electrode C2c. The second capacitor C2 includes the 2-1-th capacitor electrode C2a which is a lower capacitor electrode, the 2-2-th capacitor electrode C2b which is an intermediate capacitor electrode, and the 2-3-th capacitor electrode C2c which is an upper capacitor electrode.

The 2-1-th capacitor electrode C2a is disposed on the first substrate 110. The 2-1-th capacitor electrode C2a is disposed on the same layer as the light shielding layer BSM and may be formed of the same material.

The 2-2-th capacitor electrode C2b is disposed on the buffer layer 111 and the gate insulating layer 112. The 2-2-th capacitor electrode C2b is disposed on the same layer as the gate electrode GE and may be formed of the same material.

The 2-3-th capacitor electrode C2c is disposed on the first interlayer insulating layer 113. The 2-3-th capacitor electrode C2c may be configured by a first layer C2cl and a second layer C2c2. The first layer C2cl of the 2-3-th capacitor electrode C2c may be formed on the same layer as the 1-2-th capacitor electrode C1b with the same material. The first layer C2cl may be disposed so as to overlap the 2-1-th capacitor electrode C2a and the 2-2-th capacitor electrode C2b with the first interlayer insulating layer 113 therebetween.

The second layer C2c2 of the 2-3-th capacitor electrode C2c is disposed on the second interlayer insulating layer 114. The second layer C2c2 is a part extending from the source electrode SE of the driving transistor DT and may be connected to the first layer C2cl through the contact hole of the second interlayer insulating layer 114.

Accordingly, the second capacitor C2 is electrically connected between the source electrode SE of the driving transistor DT and the light emitting diode ED to increase capacitance inherent in the light emitting diode ED and allow the light emitting diode ED to emit light with a higher luminance.

The first passivation layer 115a is disposed on the driving transistor DT, the first capacitor C1, and the second capacitor C2. The first passivation layer 115a is an inorganic insulating layer which protects components below the first passivation layer 115a and may be configured by an inorganic material, such as silicon oxide (SiOx) or silicon nitride (SiNx), but is not limited thereto.

The first planarization layer 116a is disposed on the first passivation layer 115a. The first planarization layer 116a may planarize an upper portion of the pixel circuit including the driving transistor DT. The first planarization layer 116a may be configured by a single layer or a double layer, and for example, may be configured by benzocyclobutene or an acrylic organic insulating layer.

In the meantime, in an area which does not overlap the plurality of first alignment keys AK1, the first planarization layer 116a may be disposed between a plurality of inorganic insulating layers. For example, the first planarization layer 116a may be disposed between the first passivation layer 115a and the second passivation layer 115b in an area which does not overlap the plurality of first alignment keys AK1.

Referring to FIGS. 4B and 5 together, a plurality of reflection plates RF are disposed on the first planarization layer 116a. The reflection plate RF is a configuration which reflects light emitted from the plurality of light emitting diodes ED above the first substrate 110 and may be formed with a shape corresponding to each of the plurality of sub pixels SP. One reflection plate RF may be disposed to cover the most area of one sub pixel SP. The reflection plate RF reflects the light emitted from the light emitting diode ED and may also be used as an electrode which electrically connects the light emitting diode ED and the pixel circuit. Therefore, the reflection plate RF may include various conductive layers in consideration of a light reflection efficiency and a resistance. For example, the reflection plate RF may use an opaque conductive layer, such as silver (Ag), aluminum (Al), molybdenum (Mo), titanium (Ti), or an alloy thereof and a transparent conductive layer, such as indium tin oxide, together, but the structure of the reflection plate RF is not limited thereto.

Referring to FIG. 4B, the reflection plate RF includes a first reflection plate RF1 corresponding to the first sub pixel SP1, a second reflection plate RF2 corresponding to the second sub pixel SP2, a third reflection plate RF3 corresponding to the third sub pixel SP3, and a fourth reflection plate RF4 corresponding to the fourth sub pixel SP4.

The first reflection plate RF1 includes a 1-1-th reflection plate RF1a overlapping most of the first sub pixel SP1 and a 1-2-th reflection plate RF1b overlapping the first light emitting diode 130 of the first sub pixel SP1. The 1-1-th reflection plate RF1a may reflect light emitted from the first light emitting diode 130 above the first light emitting diode 130. The 1-1-th reflection plate RF1a may be electrically connected to the source electrode SE of the driving transistor DT and the second capacitor C2 through a first contact hole CH1 of the first planarization layer 116a and the first passivation layer 115a. Therefore, the 1-1-th reflection plate RF1a may electrically connect the driving transistor DT and the first electrode 134 of the first light emitting diode 130. The 1-2-th reflection plate RF1b may reflect light emitted from the first light emitting diode 130 above the first light emitting diode 130. The 1-2-th reflection plate RF1b may serve as an electrode which electrically connects the second electrode 135 of the first light emitting diode 130 and the high potential power line VL1.

The second reflection plate RF2 includes a 2-1-th reflection plate RF2a overlapping most of the second sub pixel SP2 and a 2-2-th reflection plate RF2b overlapping the first light emitting diode 130 of the second sub pixel SP2. The 2-1-th reflection plate RF2a may reflect light emitted from the first light emitting diode 130 above the first light emitting diode 130. The 2-1-th reflection plate RF2a is electrically connected to the source electrode SE of the driving transistor DT and the second capacitor C2 through the first contact hole CH1 to transmit a driving current from the driving transistor DT to the first electrode 134 of the first light emitting diode 130. The 2-2-th reflection plate RF2b may be used as an electrode which reflects the light emitted from the first light emitting diode 130 above the first light emitting diode 130 and electrically connects the second electrode 135 of the first light emitting diode 130 to the high potential power line VL1.

The third reflection plate RF3 may be formed as one third reflection plate RF3 which overlaps the entire third sub pixel SP3. The third reflection plate RF3 may reflect light emitted from the second light emitting diode 140 of the third sub pixel SP3 above the second light emitting diode 140. The third reflection plate RF3 is electrically connected to the source electrode SE of the driving transistor DT and the second capacitor C2 through the first contact hole CH1 to transmit a driving current from the driving transistor DT to the first electrode 134 of the second light emitting diode 140.

The fourth reflection plate RF4 may be formed as one fourth reflection plate RF4 which overlaps the entire fourth sub pixel SP4. The fourth reflection plate RF4 may reflect light emitted from the third light emitting diode 150 of the fourth sub pixel SP4 above the third light emitting diode 150. The fourth reflection plate RF4 is electrically connected to the source electrode SE of the driving transistor DT and the second capacitor C2 through the first contact hole CH1 to transmit a driving current from the driving transistor DT to the first electrode 134 of the third light emitting diode 150.

In the meantime, even though it has been described that the first sub pixel SP1 and the second sub pixel SP2 are formed with two reflection plates RF and the third sub pixel SP3 and the fourth sub pixel SP4 are formed with one reflection plate RF, the reflection plate RF may be designed in various manners. For example, the plurality of reflection plates RF may be disposed in all the plurality of sub pixels SP, like the first sub pixel SP1 and the second sub pixel SP2.

For example, as illustrated in FIG. 5, the reflection plate RF may include a plurality of first reflection electrodes RFa and a plurality of second reflection electrodes RFb disposed in each of the plurality of sub pixels SP.

The plurality of first reflection electrodes RFa may reflect light emitted from the light emitting diode ED above the light emitting diode ED. The plurality of first reflection electrodes RFa is disposed in the driving transistor DT in each of the plurality of sub pixels SP to be electrically connected to the source electrode SE of the driving transistor DT and the second capacitor C2 through a first contact hole CH1.

The plurality of second reflection electrodes RFb may be disposed so as to overlap the light emitting diode ED. The plurality of second reflection electrodes RFb may be electrically connected to the high potential power line VL1 through a second contact hole CH2 in each of the plurality of sub pixels SP. Therefore, the plurality of second reflection electrodes RFb may reflect the light emitted from the light emitting diode ED to the outside of the display device 100 while supplying the high potential power voltage to the light emitting diode ED.

In the meantime, all the first light emitting diode 130, the second light emitting diode 140, and the third light emitting diode 150 are separately connected to the high potential power line VL1 without having the reflection plate RF, but are not limited thereto.

Referring to FIG. 5, the second passivation layer 115b is disposed on the plurality of reflection plates RF. The second passivation layer 115b is an inorganic insulating layer which protects components below the second passivation layer 115b and may be configured by a single layer or a double layer of silicon oxide (SiOx) or silicon nitride (SiNx), but is not limited thereto.

The adhesive layer AD is disposed on the second passivation layer 115b. The adhesive layer AD is formed on the entire surface of the first substrate 110 to fix the light emitting diode ED disposed on the adhesive layer AD. The adhesive layer AD may be formed of an organic insulating layer. The adhesive layer AD may be formed of a photo curable adhesive material which is cured by light. For example, the adhesive layer AD may be formed of an acrylic material including a photoresist, but is not limited thereto. The adhesive layer AD may be formed on the entire surface of the first substrate 110 excluding a pad area in which the first pad electrode PAD1 is disposed.

The plurality of light emitting diodes ED are disposed in each of the plurality of sub pixels SP on the adhesive layer AD. The light emitting diode ED is an element which emits light by a current and may include a first light emitting diode 130 which emits red light, a second light emitting diode 140 which emits green light, and a light emitting diode ED which emits blue light and may implement light with various colors including white by a combination thereof. For example, the light emitting diode ED may be a light emitting diode (LED) or a micro LED, but is not limited thereto.

One first light emitting diode 130 is disposed in each of the first sub pixel SP1 and the second sub pixel SP2, one pair of second light emitting diodes 140 is disposed in the third sub pixel SP3, and one pair of third light emitting diodes 150 is disposed in the fourth sub pixel SP4. That is, two first light emitting diodes 130, two second light emitting diodes 140, and two third light emitting diodes 150 may be disposed in one pixel PX. At this time, each of the first light emitting diodes 130 is connected to the driving transistor DT of each of the first sub pixel SP1 and the second sub pixel SP2 to be individually driven. In contrast, one pair of second light emitting diodes 140 of the third sub pixel SP3 and one pair of third light emitting diodes 150 of the fourth sub pixel SP4 are connected to one driving transistor DT in parallel to be driven.

The plurality of light emitting diodes ED include a first semiconductor layer 131, an emission layer 132, a second semiconductor layer 133, a first electrode 134, and a second electrode 135.

The first semiconductor layer 131 is disposed on the adhesive layer AD and the second semiconductor layer 133 is disposed on the first semiconductor layer 131. The first semiconductor layer 131 and the second semiconductor layer 133 may be layers formed by doping n-type and p-type impurities into a specific material. For example, the first semiconductor layer 131 and the second semiconductor layer 133 may be layers doped with n-type and p-type impurities into a material such as gallium nitride (GaN), indium aluminum phosphide (InAlP), or gallium arsenide (GaAs). The p-type impurity may be magnesium (Mg), zinc (Zn), beryllium (Be), and the like, and the n-type impurity may be silicon (Si), germanium, tin (Sn), and the like, but they are not limited thereto.

The emission layer 132 is disposed between the first semiconductor layer 131 and the second semiconductor layer 133. The emission layer 132 is supplied with holes and electrons from the first semiconductor layer 131 and the second semiconductor layer 133 to emit light. The emission layer 132 may be formed by a single layer or a multi-quantum well (MQW) structure, and for example, may be formed of indium gallium nitride (InGaN), gallium nitride (GaN), or the like, but is not limited thereto.

The first electrode 134 is disposed on the first semiconductor layer 131. The first electrode 134 is an electrode which electrically connects the driving transistor DT and the first semiconductor layer 131. In this case, the first semiconductor layer 131 is a semiconductor layer doped with an n-type impurity and the first electrode 134 may be a cathode. The first electrode 134 may be disposed on a top surface of the first semiconductor layer 131 which is exposed from the emission layer 132 and the second semiconductor layer 133. The first electrode 134 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 135 is disposed on the second semiconductor layer 133. The second electrode 135 may be disposed on the top surface of the second semiconductor layer 133. The second electrode 135 is an electrode which electrically connects the high potential power line VL1 and the second semiconductor layer 133. In this case, the second semiconductor layer 133 is a semiconductor layer doped with a p-type impurity and the second electrode 135 may be an anode. The second electrode 135 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, an encapsulation film 136 which encloses the first semiconductor layer 131, the emission layer 132, the second semiconductor layer 133, the first electrode 134, and the second electrode 135 is disposed. The encapsulation film 136 is formed of an insulating material to protect the first semiconductor layer 131, the emission layer 132, and the second semiconductor layer 133. In the encapsulation film 136, a contact hole which exposes the first electrode 134 and the second electrode 135 is formed to electrically connect a first connection electrode CE1 and a second connection layer CE2 to the first electrode 134 and the second electrode 135.

In the meantime, a part of the side surface of the first semiconductor layer 131 may be exposed from the encapsulation film 136. The light emitting diode ED manufactured on the wafer is separated from the wafer to be transferred to the display panel PN. However, during the process of separating the light emitting diode ED from the wafer, a part of the encapsulation film 136 may be torn. For example, a part of the encapsulation film 136 which is adjacent to a lower edge of the first semiconductor layer 131 of the light emitting diode ED is torn during the process of separating the light emitting diode ED from the wafer. Accordingly, a part of a lower side surface of the first semiconductor layer 131 may be exposed to the outside. However, even though the lower portion of the light emitting diode ED is exposed from the encapsulation film 136, the first connection electrode CE1 and the second connection electrode CE2 are formed after forming the second planarization layer 116b and the third planarization layer 116c which cover the side surface of the first semiconductor layer 131. Accordingly, a short defect may be reduced.

Next, the second planarization layer 116b and the third planarization layer 116c are disposed on the adhesive layer AD and the light emitting diode ED.

The second planarization layer 116b overlaps a part of the side surfaces of the plurality of light emitting diodes ED to fix and protect the plurality of light emitting diodes ED. The second planarization layer 116b may be configured by a single layer or a double layer, and for example, configured by benzocyclobutene or an acrylic organic insulating layer. The second planarization layer 116b may be formed using a halftone mask. Therefore, the second planarization layer 116b may be formed to have a step.

Specifically, a part of the second planarization layer 116b which is relatively adjacent to the light emitting diode ED may be formed to have a smaller thickness and a part which is farther from the light emitting diode ED may be formed to have a larger thickness. A part of the second planarization layer 116b which is adjacent to the light emitting diode ED may be disposed to enclose the light emitting diode ED and may also be in contact with a side surface of the light emitting diode ED. Therefore, a torn part of the encapsulation film 136 which protects a side surface of the first semiconductor layer 131 of the light emitting diode ED during the process of separating the light emitting diode ED from the wafer to be transferred to the display panel PN may be covered by the second planarization layer 116b. By doing this, thereafter, contacts and short defects of the connection electrodes CE1 and CE2 and the first semiconductor layer 131 may be suppressed.

The third planarization layer 116c is formed to cover upper portions of the second planarization layer 116b and the light emitting diode ED and a contact hole which exposes the first electrode 134 and the second electrode 135 of the light emitting diode ED may be formed. The first electrode 134 and the second electrode 135 of the light emitting diode ED are exposed from the third planarization layer 116c and the third planarization layer 116c is partially disposed in an area between the first electrode 134 and the second electrode 135 to reduce a short defect. The second planarization layer 116b and the third planarization layer 116c may be configured by a single layer or a double layer, and for example, may be formed of photoresist or an acrylic organic insulating material.

In the meantime, the third planarization layer 116c may cover the light emitting diode ED and an area adjacent to the light emitting diode ED. The third planarization layer 116c may be disposed in an area of the sub pixel SP enclosed by the bank BB and may be disposed in an island shape. Therefore, a bank BB may be disposed on a part of the top surface of the second planarization layer 116b. For example, the bank BB may be disposed on the third planarization layer 116c so as to overlap a part of the third planarization layer 116c.

The first connection electrode CE1 and the second connection electrode CE2 are disposed on the third planarization layer 116c.

The first connection electrode CE1 is an electrode which electrically connects the first electrode 134 of the light emitting diode ED and the driving transistor DT. The first connection electrode CE1 may be electrically connected to the first electrode 134 exposed from the third planarization layer 116c and may be electrically connected to the first reflection electrode RFa through a contact hole formed in the third planarization layer 116c, the second planarization layer 116b, the adhesive layer AD, and the second passivation layer 115b, simultaneously. Therefore, the first electrode 134 and the source electrode SE of the driving transistor DT may be electrically connected by means of the first connection electrode CE1 and the first reflection electrode RFa.

The second connection electrode CE2 is an electrode which electrically connects the second electrode 135 of the light emitting diode ED and the high potential power line VL1. The second connection electrode CE2 may be electrically connected to the second electrode 135 exposed from the third planarization layer 116c and may be electrically connected to the second reflection electrode RFb through a contact hole formed in the third planarization layer 116c, the second planarization layer 116b, the adhesive layer AD, and the second passivation layer 115b. Accordingly, the second electrode 135 and the high potential power line VL1 may be electrically connected through the second connection electrode CE2.

The first connection electrode CE1 and the second connection electrode CE2 may be formed of a transparent conductive material, such as indium tin oxide (ITO) or indium zinc oxide (IZO), but are not limited thereto.

In the meantime, in the drawing, it is illustrated that the first electrode 134, the first connection electrode CE1, and the first reflection electrode RFa are electrically connected to the source electrode SE of the driving transistor DT. However, the first electrode 134, the first connection electrode CE1, and the first reflection electrode RFa may be connected to the drain electrode DE of the driving transistor DT, but it is not limited thereto.

Referring to FIG. 5, the bank BB is disposed on the first connection electrode CE1 and the second connection electrode CE2, and the second planarization layer 116b exposed from the third planarization layer 116c. The bank BB may be disposed to be spaced apart from the light emitting diode ED with a predetermined interval and may at least partially overlap the reflection plate RF. For example, the bank BB may cover a part of the first connection electrode CE1 and the second connection electrode CE2 formed in the contact holes of the third planarization layer 116c and the second planarization layer 116b. Further, the bank BB may be disposed on the second planarization layer 116b with a predetermined interval from the light emitting diode ED.

The bank BB may be formed of an opaque material to reduce color mixture between the plurality of sub pixels SP and for example, may be formed of black resin, but is not limited thereto.

In the meantime, a thickness of a part of the bank BB which is formed in the contact holes of the third planarization layer 116c and the second planarization layer 116b to cover a part of the first connection electrode CE1 and the second connection electrode CE2 and a thickness of a part disposed on the second planarization layer 116b may be different from each other. Specifically, when the part of the bank BB covers a part of the first connection electrode CE1 and the second connection electrode CE2 formed in the contact holes of the third planarization layer 116c and the second planarization layer 116b, since the contact hole is formed from the second passivation layer 115b to the third planarization layer 116c, the bank BB may be disposed below the light emitting diode ED, that is, disposed to be lower than the light emitting diode ED. Therefore, the thickness of the part of the bank BB which covers a part of the first connection electrode CE1 and the second connection electrode CE2 formed in the contact holes of the third planarization layer 116c and the second planarization layer 116b may be larger than the thickness of a part of the bank BB disposed on the second planarization layer 116b.

However, it is not limited thereto and the bank BB may be disposed at the outside of the contact holes of the third planarization layer 116c and the second planarization layer 116b to cover a part of the first connection electrode CE1 and the second connection electrode CE2.

A first protection layer 117 is disposed on the first connection electrode CE1, the second connection electrode CE2, and the bank BB. The first protection layer 117 is a layer which protects components below the first protection layer 117. The first protection layer 117 may be configured by a single layer or a double layer, and for example, configured by benzocyclobutene, a light-transmitting epoxy, a photoresist, or an acrylic organic material, but is not limited thereto.

A second substrate 120 is disposed below the first substrate 110. The second substrate 120 is a substrate which supports components disposed below the display device 100 and may be an insulating substrate. For example, the second substrate 120 may be formed of glass, resin, or the like. Further, the second substrate 120 may include polymer or plastic. The second substrate 120 may be formed of the same material as the first substrate 110. In some exemplary embodiments, the second substrate 120 may be formed of a plastic material having flexibility.

A bonding layer BDL is disposed between the first substrate 110 and the second substrate 120. The bonding layer BDL may be formed of a material which is cured by various curing methods to bond the first substrate 110 and the second substrate 120. The bonding layer BDL may be disposed only in a partial area between the first substrate 110 and the second substrate 120 or may be disposed in the entire area therebetween.

The second protection layer 121 is disposed below the second substrate 120. The second protection layer 121 may protect various wiring lines and driving components formed on the second substrate 120. The second protection layer 121 may be configured by an organic insulating material, and for example, configured by benzocyclobutene or an acrylic organic insulating material, but is not limited thereto.

The encapsulation layer 160 is disposed above the first protection layer 117 and below the second protection layer 121. The encapsulation layer 160 is a layer which minimizes the moisture permeation from the outside of the display device 100 to encapsulate a component enclosed by the encapsulation layer 160. The encapsulation layer 160 may be disposed to enclose front surfaces, side surfaces, and rear surfaces of the first substrate 110 and the second substrate 120.

The encapsulation layer 160 may be formed of a material having a low moisture permeability and a high insulating property. For example, the encapsulation layer 160 may be formed of a material including parylene, but is not limited thereto.

Next, even though it is not illustrated in FIG. 5, the plurality of side lines SRL is disposed on the side surfaces of the first substrate 110 and the second substrate 120. The plurality of side lines SRL may electrically connect the plurality of first pad electrodes PAD1 formed on the top surface of the first substrate 110 and the plurality of second pad electrodes PAD2 formed on the rear surface of the second substrate 120. The plurality of side lines SRL may be disposed so as to enclose the side surface of the display device 100. Each of the plurality of side lines SRL may cover the first pad electrode PAD1 at an end portion of the first substrate 110, a side surface of the first substrate 110, a side surface of the second substrate 120, and the second pad electrode PAD2 at an end portion of the second substrate 120. For example, the plurality of side lines SRL may be formed by a pad printing method using a conductive ink including, for example, silver (Ag), copper (Cu), molybdenum (Mo), and chrome (Cr).

A side insulating layer which covers the plurality of side lines SRL may be disposed. The side insulating layer may be formed on the top surface of the first substrate 110, the side surface of the first substrate 110, the side surface of the second substrate 120, and the rear surface of the second substrate 120 to cover the side line SRL. The side insulating layer may protect the plurality of side lines SRL.

In the meantime, when the plurality of side lines SRL is formed of a metal material, there may be a problem in that external light is reflected from the plurality of side lines SRL or light emitted from the light emitting diode ED is reflected from the plurality of side lines SRL to be visibly recognized by the user. Therefore, the side insulating layer is configured to include a black material to suppress reflection of the external light. For example, the side insulating layer may be formed by a pad printing method using an insulating material including a black material, for example, a black ink.

A seal member 150 which covers the side insulating layer is disposed. The seal member 150 is disposed so as to enclose the side surface of the display device 100 to protect the display device 100 from external impacts, moisture, and oxygen. For example, the seal member 150 may be formed of polyimide (PI), poly urethane, epoxy, or acryl-based insulating material, but is not limited thereto. In the meantime, the seal member 150 extends from a side surface of the display device 100 so as to cover a part of the bottom surface of the display device 100 as illustrated in FIG. 5, but it is not limited thereto.

Referring to FIG. 5, an optical film MF which covers an upper portion of the encapsulation layer 160 is disposed in the entire area of the top of the first substrate 110. The optical film MF may be disposed on the seal member 150, the side insulating layer, and the first protection layer 117. The optical film MF may be a functional film which implements a higher quality of images while protecting the display device 100. For example, the optical film MF may include an anti-scattering film, an anti-glare film, an anti-reflecting film, a low-reflecting film, an OLED transmittance controllable film, a polarizer, or the like, but is not limited thereto.

An adhering unit 118 is disposed between the first protection layer 117 and the optical film MF above the first substrate 110. The adhering unit 118 is formed on the front surface of the first substrate 110 to bond between the first protection layer 117 and the optical film MF. The adhering unit 118 may be formed of a photo curable adhesive material which is cured by light. For example, the adhering unit 118 may be formed of an acrylic material including a photoresist, but is not limited thereto.

In the present disclosure, the adhering unit 118 and the optical film MF are defined as separate components, but the present disclosure is not limited thereto and the optical film MF and the adhering unit 118 may be defined as one component.

Hereinafter, an area in which a first alignment key AK1 of the display device 100 according to the exemplary embodiment of the present disclosure is disposed will be described with reference to FIG. 6.

FIG. 6 is a cross-sectional view taken along the line VI-VI′ of FIG. 3 according to one embodiment.

As illustrated in FIG. 5, one of the plurality of organic insulating layers may be disposed between the plurality of inorganic insulating layers, in an area which does not overlap the plurality of first alignment keys AK1 on the first substrate 110. However, referring to FIG. 6, in the area which overlaps the plurality of first alignment keys AK1, the buffer layer 111, the gate insulating layer 112, the first interlayer insulating layer 113, the second interlayer insulating layer 114, the first passivation layer 115a, the second passivation layer 115b, the adhesive layer AD, and the second planarization layer 116b are sequentially laminated. That is, in the area which overlaps the plurality of first alignment keys AK1, the plurality of organic insulating layers may be disposed on the plurality of inorganic insulating layers.

Hereinafter, for the convenience of description, an area of the first substrate 110 in which at least one organic insulating layer, among the plurality of organic insulating layers, is disposed between the plurality of inorganic insulating layers, is referred to as a first area. Further, an area of the first substrate 110 in which the plurality of organic insulating layers is disposed on the plurality of inorganic insulating layers is referred to as a second area. For example, in the first area, as illustrated in FIG. 5, the plurality of transistors and the plurality of light emitting diodes ED may be disposed and in the second area, as illustrated in FIG. 6, the plurality of first alignment keys AK1 may be disposed. Further, the first area may be disposed so as to enclose the second area.

Referring to FIG. 6, a power line, for example, a high potential power line VL1, may be disposed on the buffer layer 111, the gate insulating layer 112, the first interlayer insulating layer 113, and the second interlayer insulating layer 114.

The high potential power line VL1 may be disposed between the second interlayer insulating layer 114 and the first passivation layer 115a.

The high potential power line VL1 may be formed of the same material as the source electrode SE and the drain electrode DE of the driving transistor DT. For example, the high potential power line VL1 may be configured by a conductive material, such as copper (Cu), aluminum (Al), molybdenum (Mo), nickel (Ni), titanium (Ti), chrome (Cr), or an alloy thereof, but is not limited thereto.

The high potential power line VL1 may be disposed in the first area and may be disposed to enclose the second area. For example, the high potential power line VL1 is disposed to be spaced apart from the plurality of first alignment keys AK1 and has a hole corresponding to an area which overlaps the plurality of first alignment keys AK1 as illustrated in FIG. 6. For example, when the plurality of first alignment keys AK1 is a circle, the high potential power line VL1 may include a circular hole.

Referring to FIG. 6, the plurality of first alignment keys AK1 may be disposed on the buffer layer 111, the gate insulating layer 112, the first interlayer insulating layer 113, and the second interlayer insulating layer 114.

The plurality of first alignment keys AK1 may have a ring shape with a hole disposed in the center, but is not limited thereto.

The plurality of first alignment keys AK1 may be formed of the same material as the source electrode SE and the drain electrode DE of the driving transistor DT. For example, the high potential power line VL1 may be configured by a conductive material, such as copper (Cu), aluminum (Al), molybdenum (Mo), nickel (Ni), titanium (Ti), chrome (Cr), or an alloy thereof, but is not limited thereto.

The first passivation layer 115a is disposed on the high potential power line VL1 and the plurality of first alignment keys AK1. The first passivation layer 115a may cover a top surface and a side surface of the power line and top surfaces and side surfaces of the plurality of first alignment keys AK1 between the first area and the second area. For example, as illustrated in FIG. 6, the first passivation layer 115a may cover a top surface and a side surface of the high potential power line VL1 and top surfaces and side surfaces of the plurality of first alignment keys AK1 at the outside of the plurality of first alignment keys AK1.

The first planarization layer 116a is disposed on the first passivation layer 115a. The first planarization layer 116a may be disposed in the first area or may be disposed to enclose the second area. The first planarization layer 116a may be disposed to be spaced apart from the plurality of first alignment keys AK1. At this time, a distance between the first planarization layer 116a and the plurality of first alignment keys AK1 may be equal to a distance between the high potential power line VL1 and the plurality of first alignment keys AK1. For example, the first planarization layer 116a may include a hole corresponding to the area which overlaps the plurality of first alignment keys AK1, as illustrated in FIG. 6. For example, a hole of the first planarization layer 116a may have the same size as a hole of the high potential power line VL1. Therefore, the hole of the first planarization layer 116a may completely overlap the hole of the high potential power line VL1.

The second passivation layer 115b is disposed on the first planarization layer 116a. The second passivation layer 115b may cover the side surface of the first planarization layer 116a between the first area and the second area. For example, as illustrated in FIG. 6, the second passivation layer 115b may cover the side surface of the first planarization layer 116a at the outside of the plurality of first alignment keys AK1. Therefore, in the area which overlaps the plurality of first alignment keys AK1, the first passivation layer 115a may be in contact with a top surface of the second interlayer insulating layer 114 and may be in contact with a bottom surface of the second passivation layer 115b.

The adhesive layer AD and the second planarization layer 116b are disposed on the second passivation layer 115b.

Accordingly, in the area which overlaps the plurality of first alignment keys AK1, the plurality of inorganic layers may be disposed between the first substrate 110 and the second passivation layer 115b and the plurality of organic insulating layers may be disposed on the second passivation layer 115b. Accordingly, in the area which does not overlap the plurality of first alignment keys AK1, one of the plurality of organic insulating layers may be disposed between the plurality of inorganic insulating layers. Further, in the area which overlaps the plurality of first alignment keys AK1, the plurality of organic insulating layers may be disposed on the plurality of inorganic insulating layers. That is, the plurality of organic insulating layers may not be disposed between the first substrate 110 and the plurality of inorganic insulating layers.

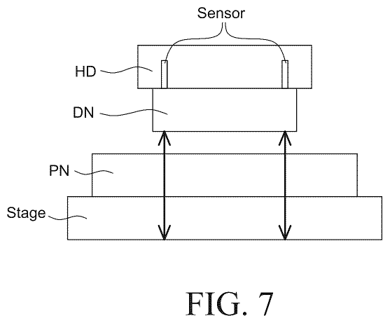

Hereinafter, a manufacturing method of the display device 100 according to an exemplary embodiment of the present disclosure will be described with reference to FIG. 7.

FIG. 7 is a schematic process diagram for explaining a manufacturing method of a display device according to an exemplary embodiment of the present disclosure. FIG. 7 is a schematic process diagram for explaining a process of aligning a degree of parallelism of a display panel PN and a donor substrate DN to transfer a plurality of light emitting diodes ED to the display panel PN.

First, the display panel PN may be fixed onto the stage and the donor substrate DN may be fixed to a head HD in which a displacement sensor is disposed.

In order to transfer the plurality of light emitting diodes ED disposed on the donor substrate DN to the display panel PN, the head HD may move onto the stage and the donor substrate DN may be aligned on the display panel PN. At this time, a plurality of first alignment keys AK1 of the display panel PN and an alignment key of the donor substrate DN are aligned to adjust a degree of parallelism between the donor substrate DN and the display panel PN.

Specifically, light is irradiated to the display panel PN and the displacement sensor disposed on the donor substrate DN detects light which is reflected from the display panel PN to return and may adjust an alignment parallelism of the donor substrate DN and the display panel PN. That is, the displacement sensor may be disposed in an area corresponding to the plurality of first alignment keys AK1 of the display panel PN and may measure optical interference which is generated by passing through the medium of the display panel PN in the area corresponding to the plurality of first alignment keys AK1. Accordingly, a distance between the donor substrate DN and the display panel PN may be measured. The donor substrate DN and the display panel PN are aligned to make phases of light measured in the plurality of first alignment keys AK1 disposed in different positions equal to each other to adjust the degree of parallelism of the donor substrate DN and the display panel PN. Accordingly, the alignment of the donor substrate DN and the display panel PN on the Z axis may be performed.

The plurality of light emitting diodes may be separated from a wafer to be transferred to the donor substrate and then may be transferred from the donor substrate to the display panel. At this time, it is very important to place the light emitting diode in a correct position of the display panel. Therefore, the donor substrate and the display panel may be aligned using the plurality of alignment keys. For example, the donor substrate and the display panel may be aligned using the plurality of alignment keys disposed in the display panel.

In the meantime, even though the alignment key of the donor substrate and the alignment key of the display panel are aligned to match, if the degree of parallelism between the donor substrate and the display panel is misaligned, the donor substrate is shifted to be bonded to the display panel. That is, when the degrees of the parallelism of the donor substrate and the display panel are different, the donor substrate may be shifted during the process of bonding the donor substrate onto the display panel and the donor substrate may be transferred to the display panel in a misaligned state of the plurality of light emitting diodes.

Therefore, after measuring the degree of parallelism between the donor substrate and the display panel, the alignment key of the donor substrate and the alignment key of the display panel may be aligned.

In the meantime, a waveform may be deformed at a boundary of a medium when the structure in which different media are laminated is repeated plural times, in an area on the substrate which overlaps the plurality of alignment keys, that is, when the organic layer is disposed between the plurality of inorganic layers or the inorganic layer is disposed between the plurality of organic layers, Therefore, a spectral interference may occur plural times in the area which overlaps the plurality of alignment keys, causing the waveform to change and during the process of bonding the donor substrate and the display panel, deviation in the X-Y plane occurs, which may reduce the alignment precision. Therefore, when the misalignment occurs, the display device may be determined as a defective product.

Accordingly, in the display device 100 according to the exemplary embodiment of the present disclosure, a hole may be formed in the first planarization layer 116a disposed between the plurality of inorganic layers to enclose the plurality of first alignment keys AK1. Therefore, in the area which overlaps the first alignment key AK1 corresponding to the sensing area of the displacement sensor, the organic layer may not be disposed between the plurality of inorganic insulating layers and the plurality of organic layers may be disposed only on the plurality of inorganic insulating layers. Accordingly, the medium change in the sensing area of the displacement sensor may be minimized and the spectral interference is minimized to improve a transfer precision of the plurality of light emitting didoes ED. Therefore, a process error in the manufacturing process of the display device 100 may be reduced to optimize the manufacturing process and improve the productivity.

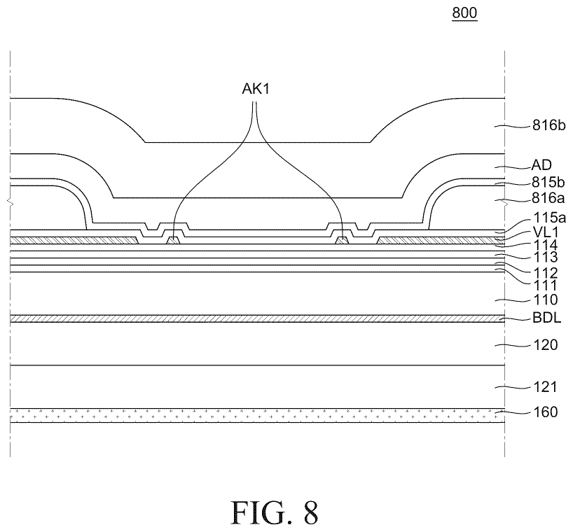

FIG. 8 is a cross-sectional view of a display device according to another exemplary embodiment of the present disclosure. The only difference between a display device 800 according to another exemplary embodiment of the present disclosure and the display device 100 according to the exemplary embodiment of the present disclosure is a first planarization layer 816a, a second passivation layer 815b, an adhesive layer AD, and a second planarization layer 816b. However, the other configuration is substantially the same so that a redundant description will be omitted.

Referring to FIG. 8, the first planarization layer 816a may include a hole corresponding to an area which overlaps the plurality of first alignment keys AK1. A width of the hole of the first planarization layer 816a may be larger than a width of a hole of the high potential power line VL1. Therefore, the hole of the first planarization layer 816a may be disposed so as to overlap a part of a top surface of the high potential power line VL1.

The second passivation layer 815b is disposed on the first planarization layer 816a. The second passivation layer 815b may cover a side surface of the first planarization layer 816a at the outside of the plurality of first alignment keys AK1 and may be in contact with the top surface of the first passivation layer 115a in an area which overlaps the plurality of first alignment keys AK1. At this time, the second passivation layer 815b may be in contact with the top surface of the first passivation layer 115a in the area which overlaps the hole of the first planarization layer 816a. As illustrated in FIG. 8, the second passivation layer 815b may be in contact with the top surface of the first passivation layer 115a in the area which overlaps the high potential power line VL1.

The adhesive layer AD and the second planarization layer 816b are disposed on the second passivation layer 815b.

Accordingly, in the area which overlaps the plurality of first alignment keys AK1, the plurality of inorganic layers may be disposed between the first substrate 110 and the second passivation layer 815b and the plurality of organic insulating layers may be disposed on the second passivation layer 815b.

Accordingly, in the display device 800 according to another exemplary embodiment of the present disclosure, a hole may be formed in the first planarization layer 816a disposed between the plurality of inorganic layers so as to enclose the plurality of first alignment keys AK1. Therefore, in the area which overlaps the first alignment keys AK1, all the plurality of organic layers are disposed on the plurality of inorganic insulating layers to minimize the spectral interference in the sensing area of the displacement sensor and improve the transfer precision of the plurality of light emitting diodes ED.

Further, in the display device 800 according to another exemplary embodiment of the present disclosure, a width of the hole of the first planarization layer 816a may be larger than a width of the hole of the high potential power line VL1. Therefore, it may be difficult to form the hole of the first planarization layer 816a and the hole of the high potential power line VL1 to exactly match during the process of forming the hole of the first planarization layer 816a. Therefore, in the display device 800 according to another exemplary embodiment of the present disclosure, a width of the hole of the first planarization layer 816a is formed to be larger than a width of the hole of the high potential power line VL1. Therefore, the first planarization layer 816a may be suppressed from being disposed in an area which overlaps the hole of the high potential power line VL1. Accordingly, a process margin of the first planarization layer 816a is ensured to improve the yield of the display device 800 and the manufacturing process may be optimized to improve the productivity.

The exemplary embodiments of the present disclosure can also be described as follows:

According to an aspect of the present disclosure, there is provided a display device. The display device comprises a substrate including an active area in which a plurality of sub pixels is disposed and a non-active area. The display device comprises a plurality of transistors disposed in each of the plurality of sub pixels on the substrate. The display device comprises a plurality of light emitting diodes disposed in each of the plurality of sub pixels on the substrate. The display device comprises a plurality of first alignment keys disposed on the substrate. The display device comprises an insulating layer which includes a plurality of inorganic insulating layers and a plurality of organic insulating layers disposed on the substrate. In an area which overlaps the plurality of first alignment keys, the plurality of organic insulating layers is disposed on the plurality of inorganic insulating layers.

In an area which does not overlap the plurality of first alignment keys, one of the plurality of organic insulating layers may be disposed between the plurality of inorganic insulating layers.

The plurality of inorganic insulating layers may include a buffer layer disposed between the substrate and the plurality of transistors, a gate insulating layer disposed between an active layer and a gate electrode of the plurality of transistors, an interlayer insulating layer disposed on the gate insulating layer, a first passivation layer disposed on the interlayer insulating layer, and a second passivation layer disposed on the first passivation layer. The plurality of organic insulating layers may include a first planarization layer disposed on the first passivation layer, an adhesive layer which is disposed on the second passivation layer and bonds the plurality of light emitting diodes, and a second planarization layer disposed on the adhesive layer.

In the area which overlaps the plurality of first alignment keys, the buffer layer, the gate insulating layer, the interlayer insulating layer, the first passivation layer, the second passivation layer, the adhesive layer, and the second planarization layer may be sequentially laminated.

The display device may further comprise a power line disposed on the substrate, wherein the power line may include a hole in the area which overlaps the plurality of first alignment keys.

The power line may be a high potential power line.

The first planarization layer may include the hole in the area which overlaps the plurality of first alignment keys and a width of the hole of the first planarization layer may be equal to or larger than a width of the hole of the power line.

The power line may be disposed between the interlayer insulating layer and the first passivation layer below the first planarization layer.

The first passivation layer may cover a side surface of the power line at an outside of the plurality of first alignment keys, the second passivation layer may cover a side surface of the first planarization layer at the outside of the plurality of first alignment keys, and in the area which overlaps the plurality of first alignment keys, the first passivation layer may be in contact with a top surface of the interlayer insulating layer and be in contact with a bottom surface of the second passivation layer.

The display device may further comprise a plurality of second alignment keys disposed along a column direction, wherein the plurality of first alignment keys may be disposed on a different column from a column in which the plurality of second alignment keys is disposed, and the plurality of first alignment keys and the plurality of second alignment keys may have different shapes.

According to another aspect of the present disclosure, there is provided a display device. The display device comprises a substrate which includes a first area and a second area. The display device comprises a plurality of transistors and a plurality of light emitting diodes disposed in the first area. The display device comprises a plurality of alignment keys disposed in the second area. The display device comprises a plurality of insulating layers disposed on the substrate in the first area and the second area. The plurality of insulating layers includes a plurality of inorganic insulating layers and a plurality of organic insulating layers disposed in the first area and the second area, in the first area, at least one of the plurality of organic insulating layers is disposed between the plurality of inorganic insulating layers, and in the second area, the plurality of organic insulating layers is disposed on the plurality of inorganic insulating layers.

The first area may be disposed so as to enclose the second area.

The display device may further comprise a power line disposed in the first area, wherein the power line may be disposed so as to enclose the second area.

The plurality of organic insulating layers may include a first planarization layer which may be disposed so as to enclose the second area on the power line.

The plurality of inorganic insulating layers may include a buffer layer disposed between the substrate and the plurality of transistors, a gate insulating layer disposed between an active layer and a gate electrode of the plurality of transistors, an interlayer insulating layer disposed on the gate insulating layer, a first passivation layer disposed on the interlayer insulating layer, and a second passivation layer disposed on the first passivation layer. The organic insulating layer may include an adhesive layer which may be disposed on the second passivation layer and bond the plurality of light emitting diodes, and a second planarization layer disposed on the adhesive layer. The first planarization layer may be disposed between the first passivation layer and the second passivation layer.

Between the first area and the second area, the first passivation layer may cover a side surface of the power line and the second passivation layer may cover a side surface of the first planarization layer.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate including an active area in which a plurality of sub pixels are disposed and a non-active area;
a plurality of transistors in each of the plurality of sub pixels on the substrate;
a plurality of light emitting diodes in each of the plurality of sub pixels on the substrate;
a plurality of first alignment keys on the substrate; and
an insulating layer on the substrate, the insulating layer including a plurality of inorganic insulating layers and a plurality of organic insulating layers,
wherein in an area which overlaps the plurality of first alignment keys, the plurality of organic insulating layers are on the plurality of inorganic insulating layers.

2. The display device according to claim 1, wherein in an area that is non-overlapping with the plurality of first alignment keys, one of the plurality of organic insulating layers is between the plurality of inorganic insulating layers.

3. The display device according to claim 1, wherein the plurality of inorganic insulating layers includes:
a buffer layer between the substrate and the plurality of transistors;
a gate insulating layer between an active layer and a gate electrode of the plurality of transistors;
an interlayer insulating layer on the gate insulating layer;
a first passivation layer on the interlayer insulating layer; and
a second passivation layer on the first passivation layer,
wherein, the plurality of organic insulating layers include:
an adhesive layer on the second passivation layer, the adhesive layer bonding the plurality of light emitting diodes; and
a second planarization layer on the adhesive layer.

4. The display device according to claim 3, wherein in the area which overlaps the plurality of first alignment keys, the buffer layer, the gate insulating layer, the interlayer insulating layer, the first passivation layer, the second passivation layer, the adhesive layer, and the second planarization layer are sequentially laminated.

5. The display device according to claim 3, further comprising:
a power line on the substrate, the power line including a hole in the area which overlaps the plurality of first alignment keys.

6. The display device according to claim 5, wherein the power line is a high potential power line.

7. The display device according to claim 5, wherein in an area that is non-overlapping with the plurality of first alignment keys, the plurality of organic insulating layers further includes a first planarization layer on the first passivation layer;
wherein the first planarization layer includes a hole in the area which overlaps the plurality of first alignment keys and a width of the hole of the first planarization layer is equal to or larger than a width of the hole of the power line.

8. The display device according to claim 7, wherein the power line is between the interlayer insulating layer and the first passivation layer below the first planarization layer.

9. The display device according to claim 8, wherein the first passivation layer covers a side surface of the power line at an outside of the plurality of first alignment keys,
wherein the second passivation layer covers a side surface of the first planarization layer at the outside of the plurality of first alignment keys,
wherein in the area which overlaps the plurality of first alignment keys, the first passivation layer is in contact with a top surface of the interlayer insulating layer and is in contact with a bottom surface of the second passivation layer.

10. The display device according to claim 1, further comprising:
a plurality of second alignment keys,
wherein the plurality of first alignment keys are on a different column from a column in which the plurality of second alignment keys are disposed, and the plurality of first alignment keys and the plurality of second alignment keys have different shapes.

11. A display device, comprising:
a substrate which includes a first area and a second area;
a plurality of transistors and a plurality of light emitting diodes in the first area;
a plurality of alignment keys in the second area; and
a plurality of insulating layers on the substrate in the first area and the second area,
wherein the plurality of insulating layers include a plurality of inorganic insulating layers and a plurality of organic insulating layers in the first area and the second area,
wherein in the first area, at least one of the plurality of organic insulating layers is between the plurality of inorganic insulating layers,
wherein in the second area, the plurality of organic insulating layers are on the plurality of inorganic insulating layers.

12. The display device according to claim 11, wherein the first area encloses the second area.

13. The display device according to claim 12, further comprising:
a power line in the first area, the power line enclosing the second area.

14. The display device according to claim 13, wherein in the first area, the plurality of organic insulating layers includes a first planarization layer that encloses the second area on the power line.

15. The display device according to claim 14, wherein the plurality of inorganic insulating layers includes:
a buffer layer between the substrate and the plurality of transistors;
a gate insulating layer between an active layer and a gate electrode of the plurality of transistors;
an interlayer insulating layer on the gate insulating layer;
a first passivation layer on the interlayer insulating layer; and
a second passivation layer on the first passivation layer,
wherein the plurality of organic insulating layers further includes:
an adhesive layer on the second passivation layer, the adhesive layer bonding the plurality of light emitting diodes; and
a second planarization layer on the adhesive layer,
wherein the first planarization layer is between the first passivation layer and the second passivation layer.

16. The display device according to claim 15, wherein between the first area and the second area, the first passivation layer covers a side surface of the power line, and the second passivation layer covers a side surface of the first planarization layer.

17. The display device according to claim 14, wherein a distance between the first planarization layer and the plurality of alignment keys is equal to a distance between the power line and the plurality of alignment keys.
